(19) United States
(12) Patent Application Publication
(10) Pub. No.: US 2026/0324428 A1
(43) Pub. Date: Oct. 15, 2026

(54) HEATSINK STANDOFF

(71) Applicant: Texas Instruments Incorporated, Dallas, TX (US)

(72) Inventor: Riccardo Ruffo, MARKT SCHWABEN (DE)

(21) Appl. No.: 19/179,155

(22) Filed: Apr. 15, 2025

(51) Int. Cl. H10W 40/60; H10W 40/20

(52) U.S. Cl. CPC H10W 40/60; H10W 40/242

(57) ABSTRACT

A heatsink standoff device includes opposite first and second sides, a package structure, an opening that extends through the package structure from the first side to the second side, and a conductive terminal exposed outside the first side and configured to be soldered to a circuit board. A method of making a heatsink standoff device includes forming a package structure having a first side and an opposite second side, forming a conductive terminal exposed outside the first side of the package structure, and forming an opening that extends through the package structure from the first side to the second side.

### BACKGROUND

Electronic devices and system designs and specifications continue to call for high power density and more components in a small area. Advances in technology, such as the integration of gallium nitride and other wideband gap semiconductor materials facilitate high power transistor operation at high voltages and frequencies. Semiconductor dies and packaged electronic devices, however, need to operate within temperature limits and thermal performance becomes more challenging as power density increases. Heatsinks can help control the operating temperature in electrical systems, for example, using power devices with top side cooling, with heatsinks for top and/or bottom side circuit board in component cooling. However, controlling the distance between a printed circuit board (PCB) and the heatsink can be challenging using standoffs with screws or soldered standoffs. Moreover, metallic standoffs can interfere with magnetic fields produced by electronic components in certain system applications. Heatsink standoffs can also be constructed by selectively milling the bottom side of an aluminum heatsink to create indented portions leaving standoff portions with the starting thickness, but this approach is expensive.

### SUMMARY

In one aspect, a heatsink standoff device includes a package structure having a first side, an opposite second side, and an opening that extends through the package structure from the first side to the second side, and a conductive terminal exposed outside the first side of the package structure and configured to be soldered to a circuit board.

In another aspect, a system includes a circuit board, an electronic component, a thermal interface material, a heatsink standoff device, and a heatsink, the circuit board having a side with a conductive pad, the electronic component spaced apart from the conductive pad and having a first side attached to the side of the circuit board, and the thermal interface material extending on an opposite second side of the electronic component. The heatsink standoff device includes a package structure having a first side attached to the side of the circuit board, an opposite second side, and an opening that extends through the package structure from the first side to the second side, and a conductive terminal exposed outside the first side of the package structure and soldered to the conductive pad of the circuit board, and the heatsink has a side with a first portion contacting the thermal interface material and a second portion attached to the second side of the package structure.

In a further aspect, a method of making a heatsink standoff device includes forming a package structure having a first side and an opposite second side, forming a conductive terminal exposed outside the first side of the package structure, and forming an opening that extends through the package structure from the first side to the second side.

### BRIEF DESCRIPTION OF THE DRAWINGS

FIG. 1 is a top perspective view of an example rectangular heatsink standoff device with a bottom side substrate and a circular opening.

FIG. 1A is a sectional side elevation view of the heatsink standoff device taken along line 1A-1A of FIG. 1.

FIG. 1B is a sectional side elevation view of the heatsink standoff device taken along line 1B-1BA of FIG. 1.

FIG. 1C is a top plan view of the heatsink standoff device of FIG. 1.

FIG. 1D is a bottom view of the heatsink standoff device of FIG. 1.

FIG. 1E is a bottom view of an alternate implementation of the heatsink standoff device with semi radial bottom side conductive terminals.

FIG. 1F is a partial sectional side elevation view of a system with a component and the heatsink standoff device mounted to a circuit board and a heatsink mounted to the heatsink standoff device using a fastener and to the top side of the component using a thermal interface material.

FIG. 1G is a top perspective view of another example rectangular heatsink standoff device with a bottom side substrate and a circular opening.

FIG. 1H is a sectional side elevation view of the heatsink standoff device taken along line 1H-1H of FIG. 1G.

FIG. 1I is a top perspective view of another example heatsink standoff device with a cylindrical shape, a bottom side substrate and a circular opening.

FIG. 1J is a sectional side elevation view of the heatsink standoff device taken along line 1J-1J of FIG. 1I.

FIG. 1K is a top plan view of the heatsink standoff device of FIG. 1I.

FIG. 1L is a bottom view of the heatsink standoff device of FIG. 1I.

FIG. 1M is a top perspective view of another example heatsink standoff device with a rectangular shape, a lateral side substrate and a circular opening.

FIG. 1N is a sectional side elevation view of the heatsink standoff device taken along line 1N-1N of FIG. 1M.

FIG. 1O is a top perspective view of another example heatsink standoff device with a rectangular shape, a lateral side substrate and a circular opening.

FIG. 1P is a sectional side elevation view of the heatsink standoff device taken along line 1P-1P of FIG. 1O.

FIG. 1Q is a bottom view of another example heatsink standoff device having a rectangular shape and a rectangular opening with planar sidewalls.

FIG. 1R is a bottom view of another example heatsink standoff device having an octagonal shape and a circular opening.

FIG. 1S is a bottom view of another example heatsink standoff device having a cylindrical shape, a circular opening and semi radial bottom side terminals.

FIG. 1T is a schematic diagram showing an example heatsink temperature sense circuit in a semiconductor die in one implementation of the heatsink standoff device of FIG. 1.

FIG. 1U is a schematic diagram showing an example heatsink voltage sense circuit in a semiconductor die in another implementation of the heatsink standoff device of FIG. 1.

FIG. 2 is a flow diagram of an example method of fabricating a heatsink standoff device.

FIG. 2A is a flow diagram of an example system assembly method.

FIGS. 3-6 are partial sectional side elevation views of the heatsink standoff device of FIG. 1 undergoing fabrication processing according to one implementation of the method of FIG. 2.

FIGS. 7-13 are partial sectional side elevation views of the system of FIG. 1F undergoing processing according to one implementation of the method of FIG. 2A.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, sides, etc., for ease of description in connection with a particular drawing, where such are not to be construed as limiting with respect to the claims. Various structures and methods of the present disclosure may be beneficially applied to an electronic apparatus such as an integrated circuit and to manufacturing electronic devices and/or systems. While such examples may be expected to provide various improvements, no particular result is a requirement of the present disclosure unless explicitly recited in a particular claim.

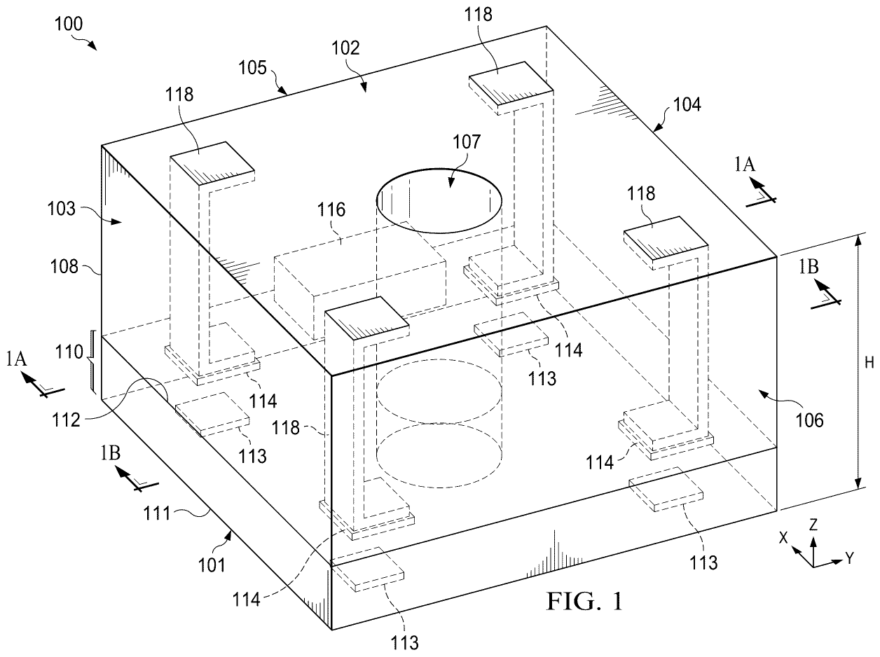

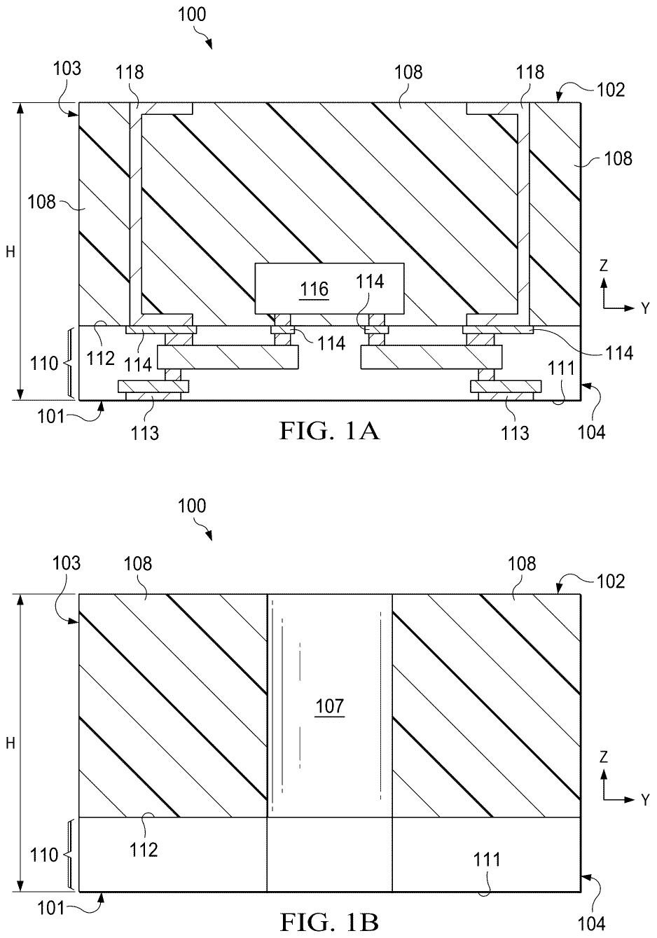

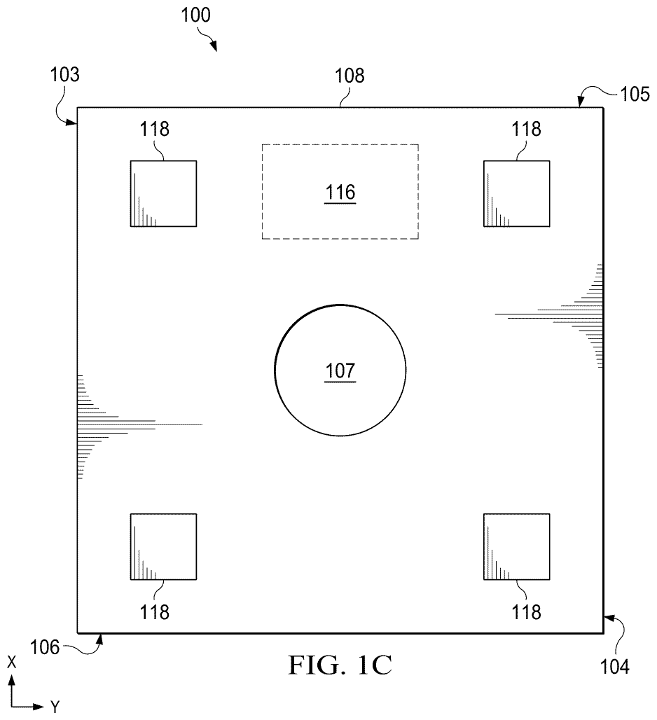

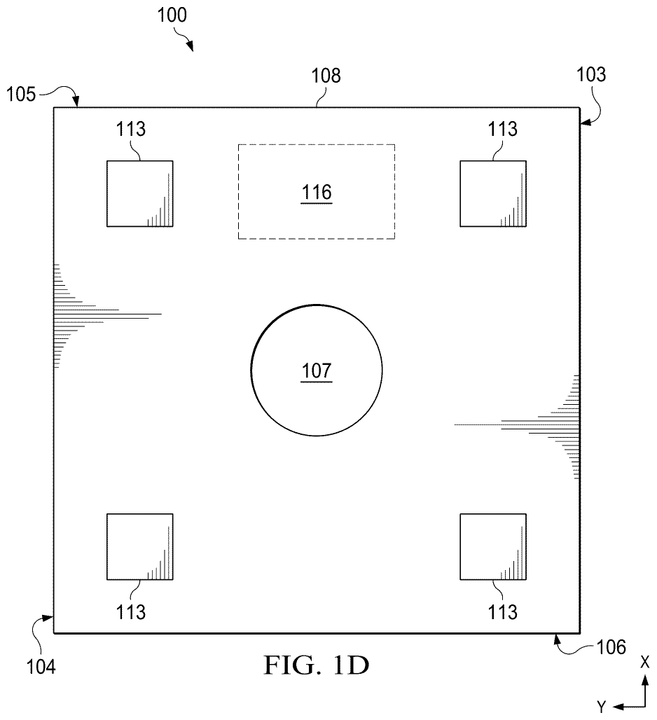

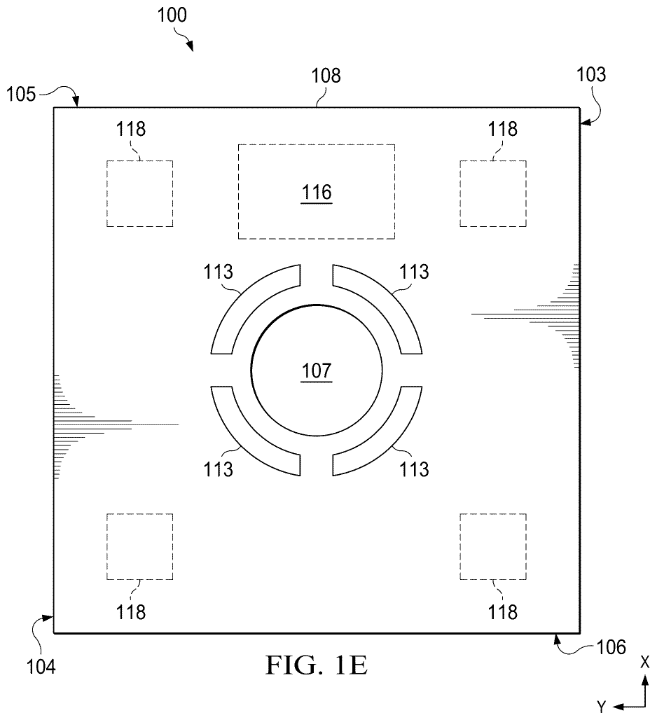

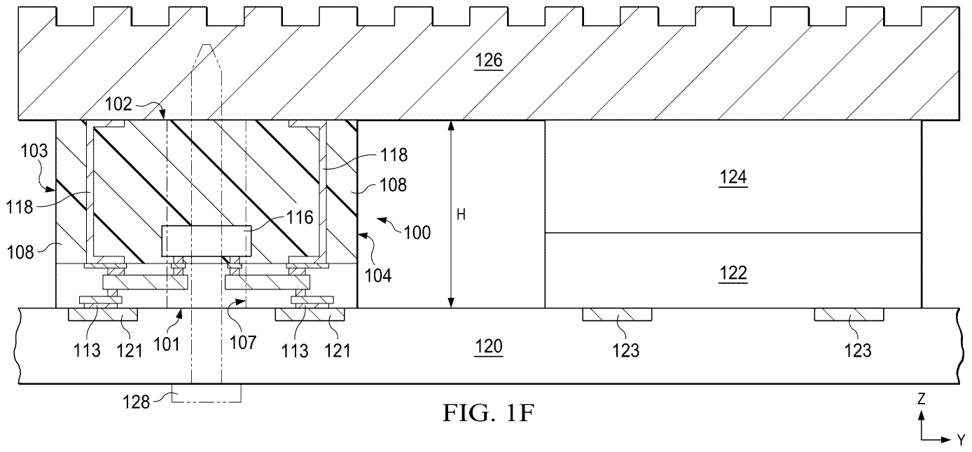

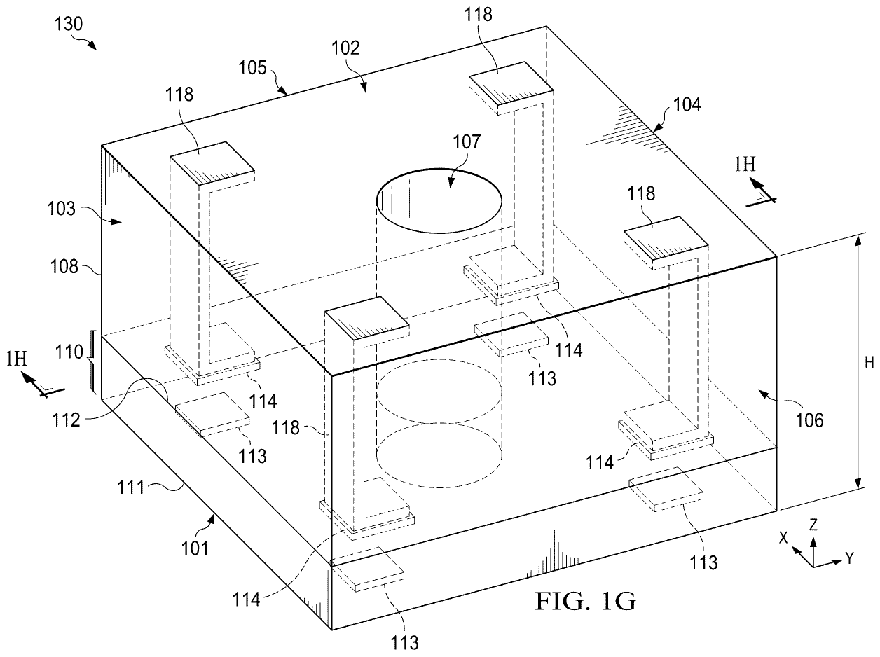

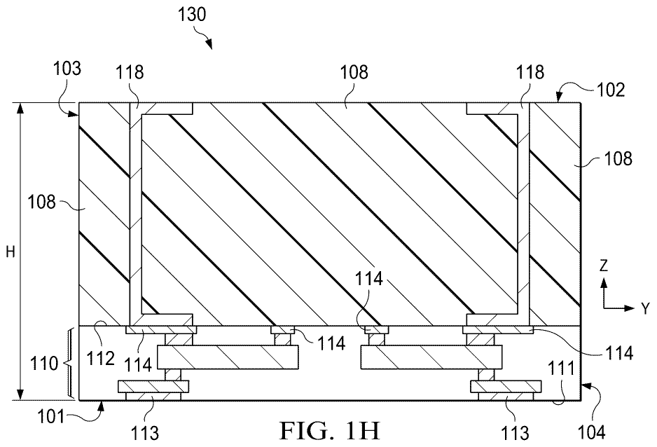

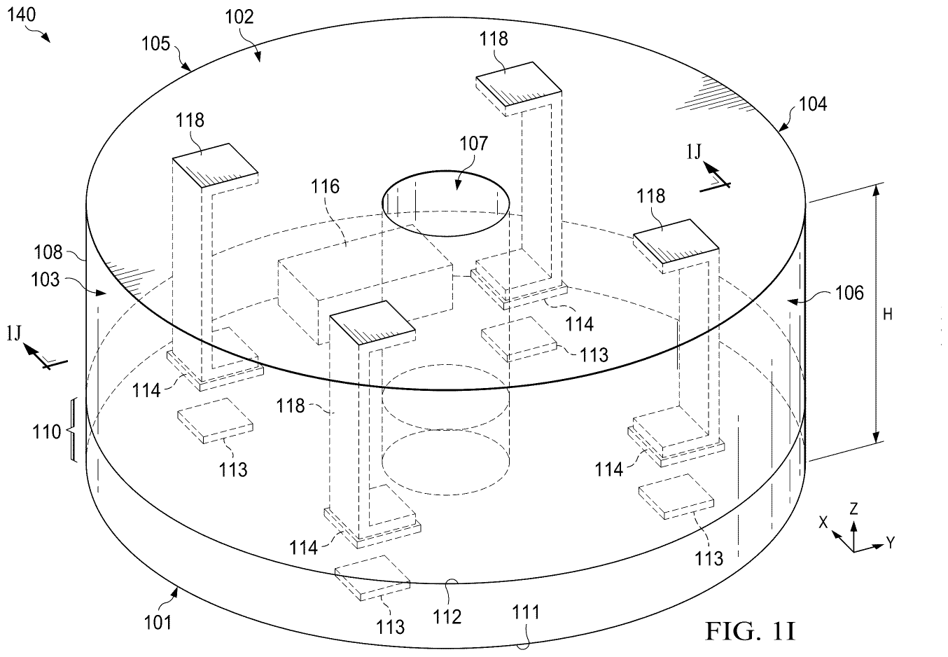

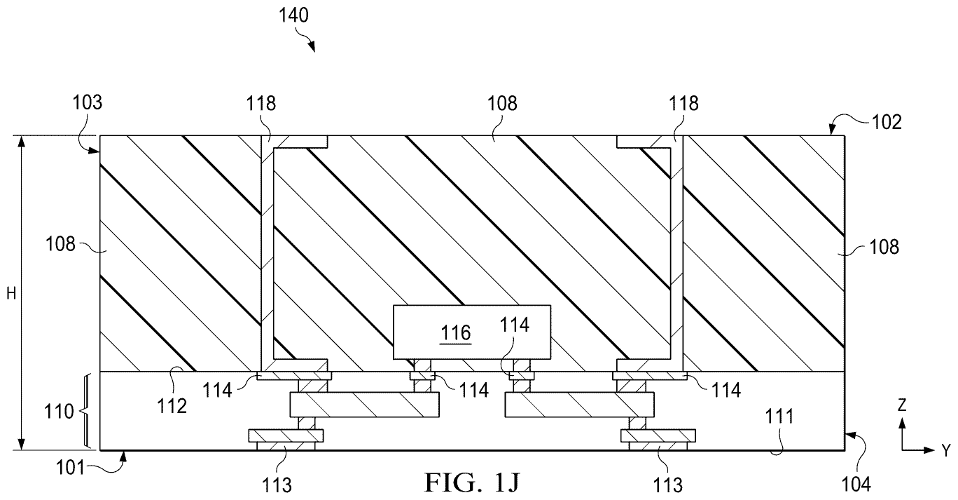

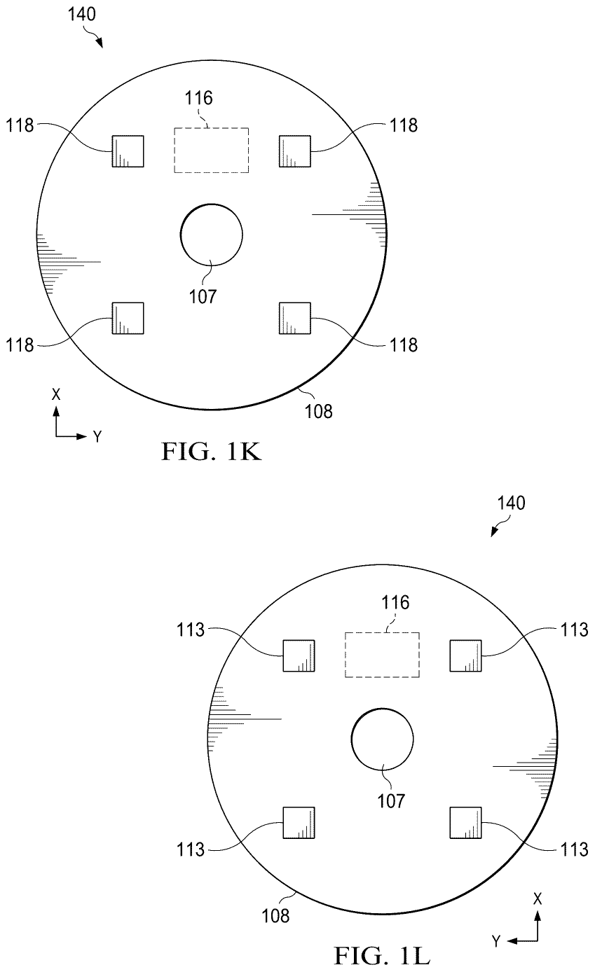

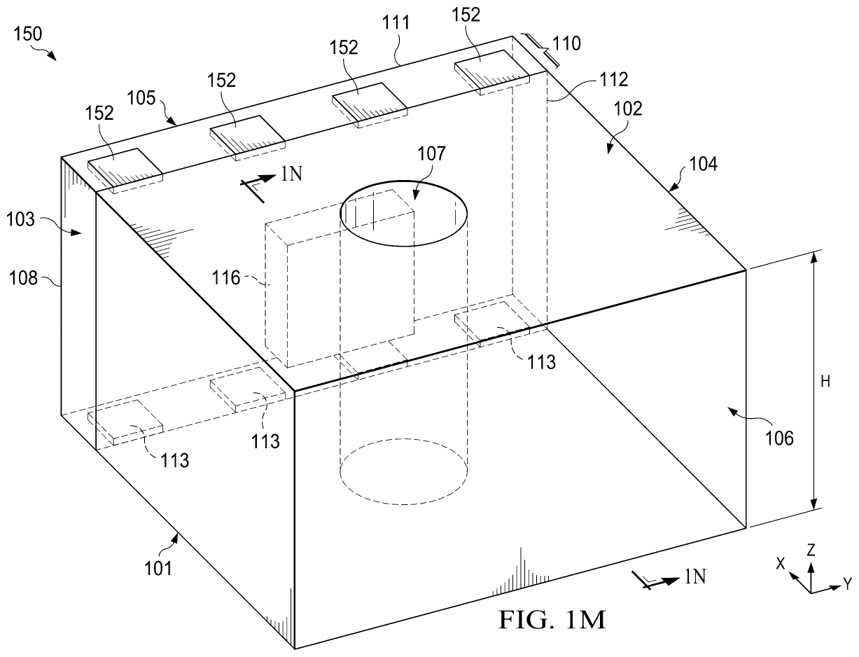

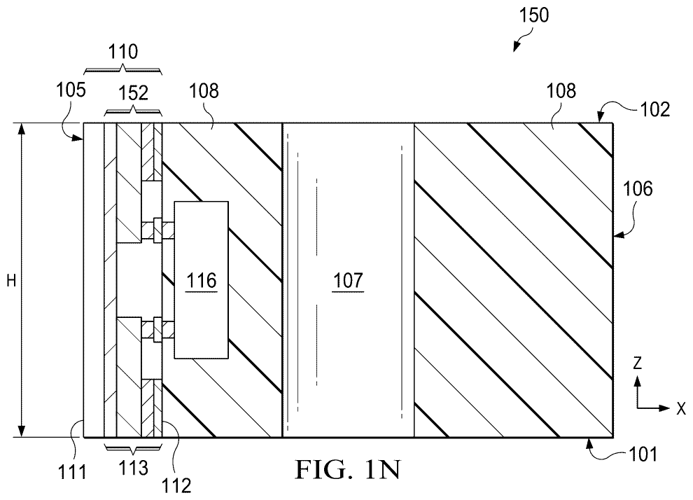

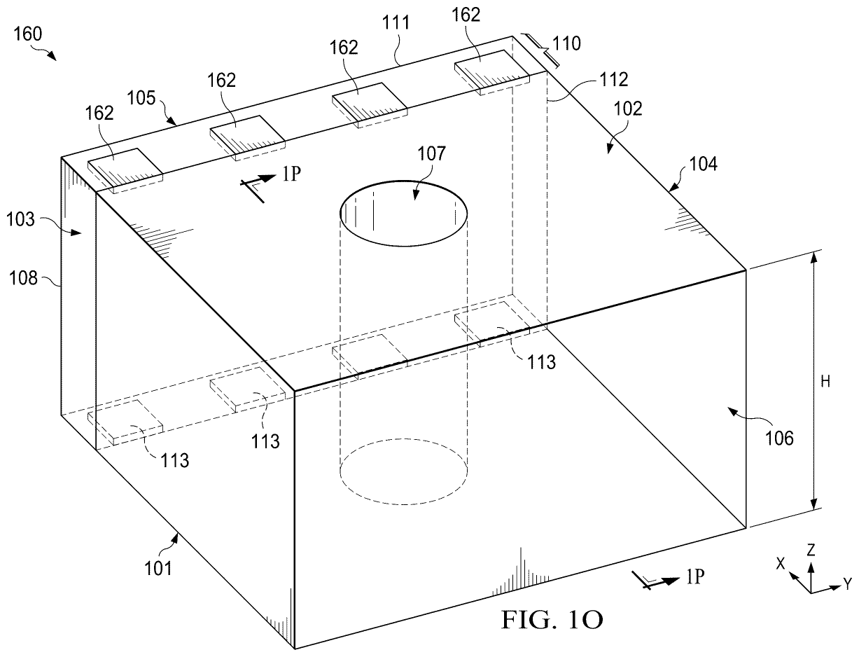

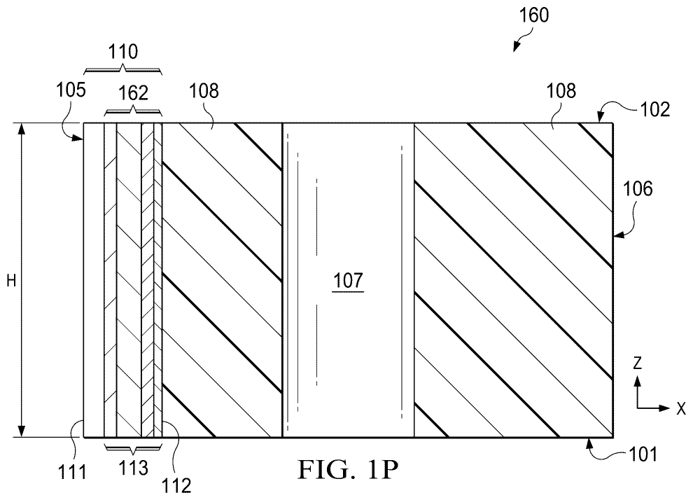

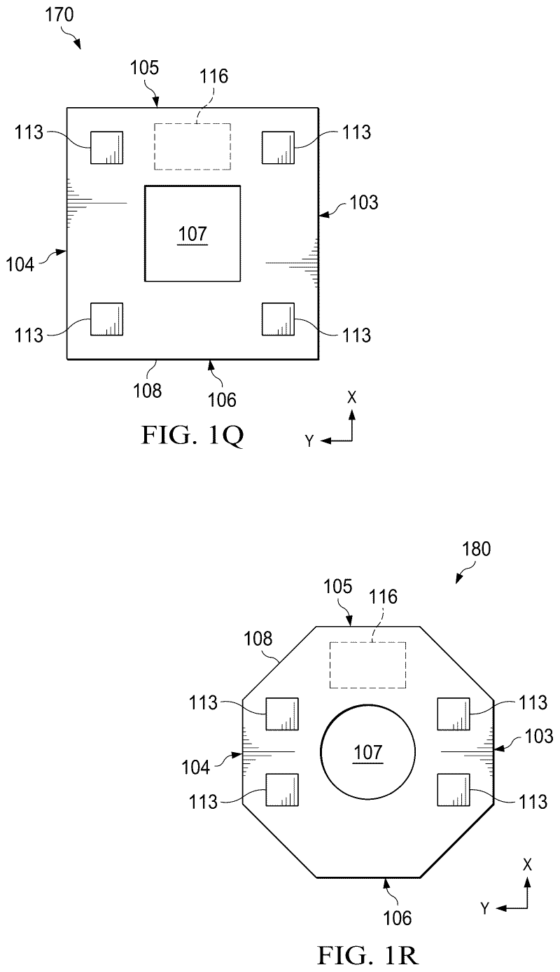

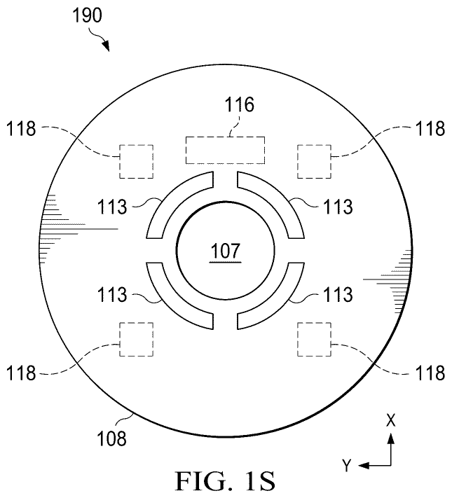

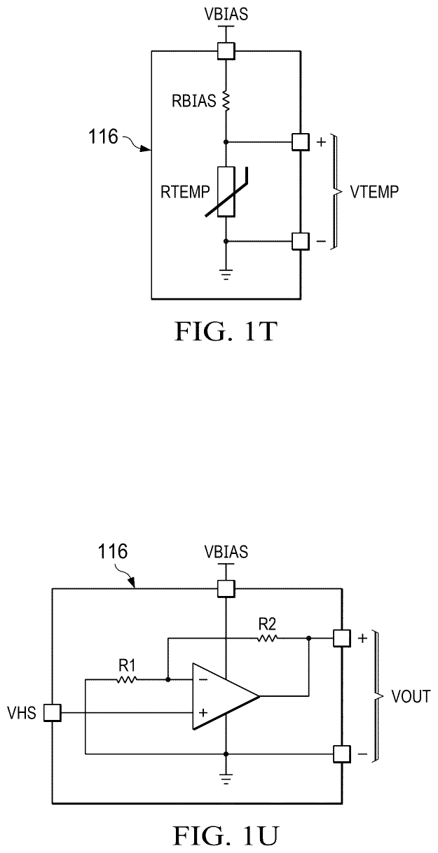

FIGS. 1-1D show an example rectangular heatsink standoff device 100 with respective first and second (e.g., bottom and top) sides 101 and 102, a molded package structure 108, a bottom side substrate 110 with a semiconductor die 116, and a circular opening 107 that extends through the package structure 108 from the first side 101 to the second side 102. The heatsink standoff device 100 is illustrated in an example position in a three-dimensional space with respective first, second, and third mutually orthogonal directions X, Y and Z. As shown in FIGS. 1-1B, the first side 101 (e.g., the bottom side) and the opposite second side 102 (e.g., top) are spaced apart from one another along the third direction Z. The heatsink standoff device 100 also includes lateral third and fourth sides 103 and 104 that are spaced apart from one another along the second direction Y, and lateral fifth and sixth sides 105 and 106 (FIGS. 1, 1C and 1D) that are spaced apart from one another along the first direction X.

The heatsink standoff device 100 includes a package structure 108, portions or features of which define or extend to the device sides 102-106. The package structure 108 has a first or bottom side that engages a second or top side 112 of the substrate 110. The package structure 108 also has a second or top side along the top side 102 of the heatsink standoff device 100. The example package structure 108 has substantially planar lateral sides 103-106, although not a requirement of all possible implementations. In other examples, the package structure can have one or more non-planar sidewalls (e.g., FIGS. 1I-1L below). In the illustrated example, the first or bottom side 101 of the heatsink standoff device 100 is defined by a first or bottom side 111 of the substrate 110 as shown in FIGS. 1-1B. In one example, the package structure 108 is or includes plastic molding compound, also referred to as epoxy molding compound (EMC), although not a requirement of all possible implementations. In another example, the package structure 108 can be or include a ceramic material (not shown).

The heatsink standoff device 100 has an opening 107 (FIGS. 1 and 1B-1D) adapted to accommodate a fastener to attach or secure a heatsink (126 in FIG. 1F below) to the second side 102 of the heatsink standoff device 100. The opening 107 can have any suitable dimensions and shape. In the example of FIGS. 1-1D, the opening 107 has a circular shape, although not a requirement of all possible implementations. In other examples, the opening 107 can include one or more linear or planar side wall portions and/or one or more curvilinear sidewalls. FIG. 1Q below shows another non-limiting example with a rectangular (e.g., square) opening having one or more planar sidewalls. As further shown in FIG. 1-1D, the opening 107 extends through the package structure 108 from the first side 101 to the second side along the third direction Z. In the illustrated example, the opening 107 also extends through the substrate 110 to the bottom or first side 101 of heatsink standoff device 100. In other examples, the heatsink standoff device can include a substrate but the opening 107 need not extend through the substrate (e.g., FIGS. 1M and 1N below).

The example heatsink standoff device 100 in FIGS. 1-1D includes the substrate 110 with a bottom or first side 111 having conductive terminals 113 exposed outside the first side 101 of the heatsink standoff device 100 along the bottom side 111 of the substrate 110 (FIGS. 1, 1A and 1D). The illustrated example has four rectangular conductive terminals 113 individually positioned between the opening 107 and an associated corner of the rectangular substrate 110, as best seen in FIGS. 1 and 1D). In other examples, the heatsink standoff device 100 can have any number of one or more conductive terminals 113 along the first side 101, and having any suitable size, shape and position. The substrate 110 in one example also includes top side conductive terminals 114 (e.g., conductive metal) along the upper or second side 112.

The conductive terminals 113 and 114 in one example are conductive metal solder pads or other conductive structures that are configured to be soldered to a circuit board (e.g., FIG. 1F below) or to another component. The substrate 110 can be any suitable single or multilevel substrate with a first side 111 (e.g., a bottom side in the illustrated orientation) and an opposite second side 112 (e.g., top) that are spaced apart from one another along the third direction Z. The substrate 110 in one example includes one or more layers or levels of dielectric with conductive metal features (e.g., copper pads, aluminum pads, etc.) exposed along each of the first and second sides 111 and 112, as well as conductive routing features (e.g., metal traces and vias) forming a routing electrical interconnection of the conductive metal features 113 and 114 exposed along the respective sides 111 and 112.

The heatsink standoff device 100 in one example is an integrated circuit (IC) with multiple included electrical or electronic components. The heatsink standoff device 100 includes a semiconductor die 116 (e.g., FIGS. 1 and 1A) attached to the second side 112 of the substrate 110 and enclosed by the package structure 108. In another example, the substrate 110 can include further electronic components and/or additional dies (not shown). In one example, the semiconductor die 116 has conductive metal pillars or solder bumps that are flip chip soldered to corresponding solder pad conductive terminals 114 along the second side 112 of the substrate 110, as shown in FIG. 1A. In one example, an underfill material (not shown) is formed between the bottom side of the semiconductor die 116 and the top side 112 of the substrate 110, although not a requirement of all possible implementations. The semiconductor die 116 in one example has one or more terminals that are electrically coupled to respective ones of the bottom side conductive terminal 113 of the substrate 110.

In addition to the bottom side terminals 113, the example heatsink standoff device 100 in FIGS. 1-1D includes a second set of conductive terminals exposed outside the package structure 108 along the second side 102. In other examples, the top side terminals can be omitted. In the illustrated example, the heatsink standoff device 100 includes metal clips 118 (FIGS. 1, 1A and 1C) that have bottoms soldered to corresponding solder pad conductive terminals 114 along the second side 112 of the substrate 110 (FIGS. 1 and 1A) and top sides that form respective second conductive terminals 118 exposed outside the package structure 108 along the second side 102 of the heatsink standoff device 100. The illustrated example has four C-shaped metal clips 118 with rectangular feet or bases soldered to respective conductive terminals 114 along the second side 112 of the substrate 110. The respective clips 118 extend from the substrate 110 to the second side 102 of the package structure 108 and include rectangular tops that form the respective second set of conductive terminals exposed outside the package structure 108 along the second side 102. In other examples, the heatsink standoff device 100 can have any number of one or more second conductive terminals 118 exposed along the second side 102, having any suitable size, shape and position. In another implementation, one or more top side second conductive terminals 118 can be implemented using a lead frame or portions of a starting lead frame (not shown) during fabrication of the heatsink standoff device 100. In further implementations, the second conductive terminals 118 can be omitted.

In the illustrated example, the substrate 110 provides electrical interconnection of the semiconductor die 116 with one or more of the top side second terminals (e.g., implemented as clips 118) and/or with the bottom side conductive terminals 113 and/or between the top side terminals 118 and the bottom side terminals 113. This allows the use of the heatsink standoff device 100 as a mechanical support having a predetermined height H (FIGS. 1-1B) to control the spacing between a top side mounted heatsink (e.g., 126 in FIG. 1F below) and a circuit board (e.g., 120 in FIG. 1F). The second side 112 of the substrate 110 includes conductive metal features to which the semiconductor die 116 is electrically coupled, and other implementations can include further semiconductor dies and/or other electronic components (not shown) attached to the second side 112 of the substrate 110 and associated electrical connections by flip chip or surface mount soldering and/or bond wires (not shown).

Certain implementations of the heatsink standoff device 100 provide electrical interconnections by soldering of the first conductive contacts 113 to corresponding solder pads of a host printed circuit board. The circuit board electrical signal connections can be used to provide a direct electrical connection to a top side mounted heatsink, for example, to allow circuitry of the host circuit board to measure a voltage and/or temperature of an installed heatsink. In addition, the heatsink standoff device 100 can be used to provide electrical isolation between a top side mounted heatsink and a circuit board to which the device 100 is attached (e.g., by omitting the top side second conductive terminals 118). The illustrated example of FIGS. 1-D can operate as an integrated circuit, including the semiconductor die 116 and/or other circuit components with electrical connections to components and circuits of a host circuit board (e.g., via the first conductive contacts 113). The substrate 110 can be designed with any suitable electrical interconnection of components mounted to the second side 112 of the substrate 110 and respective first conductive terminals 113. In one example, the semiconductor die 116 can perform one or more measurements (e.g., heatsink temperature, heatsink voltage) via the electrical connections through the clips 118 to an installed heatsink (e.g., FIG. 1F below) and provide a measurement output signal (e.g., a voltage signal indicating the temperature of the heatsink and/or a voltage of the heatsink) to a circuit or component of the host circuit board via the electrical connection through the first conductive terminals 113.

The heatsink standoff device 100 can be used as a low-cost alternative to metallic standoffs to provide benefits in terms of the ability to customize the height H for a given circuit board for improved thermal performance. In addition, the heatsink standoff device 100 can provide electrical interconnections and integrated circuit operations within the heatsink standoff device 100. In certain implementations, the heatsink standoff device 100 can be fabricated using semiconductor packaging materials and assembly processes to provide cost savings compared with commercially available metal standoffs. The opening 107 in certain implementations facilitates use of a screw, bolt, or other fastener to secure a heatsink to the second side 102 of the heatsink standoff device 100 and to a circuit board to which the standoff device 100 is attached. In another application, it may be beneficial to connect a high voltage floating potential (e.g., a supply neutral or other floating reference) to a heatsink, for example, to improve system level electro-magnetic interference (EMI) performance. In such circumstances, an implementation of the heatsink standoff device 100 can connect the high voltage floating potential from a host circuit board to the heatsink while operating as a mechanical standoff to provide a compact, low cost solution without any additional components. In another application, the heatsink standoff device 100 can be used as a board to board connector with the first side 102 connected to a first circuit board and the second side 102 connected to a second circuit board for example, to connect one or more signals (e.g., power supply rails, communications signals, etc.) from one board to another.

In implementations where one or more conditions of an installed heatsink is beneficial, the heatsink standoff device 100 can provide electrical circuit connections, for example, by his power (e.g., 3.3 V), ground, input and/or output signal routing. For example, the second conductive terminals 118 can be configured to be electrically coupled to a heatsink (e.g., FIG. 1F) and the semiconductor die 116 can be electrically coupled to the second conductive terminal 118, for example, to measure a voltage and/or temperature of the installed heatsink. In one implementation, the semiconductor die 116 can include a temperature sensing circuit (e.g., FIG. 1T below) to provide a heatsink temperature signal to one of the conductive terminals 113 so that circuitry of the host circuit board can use the measured heatsink temperature information, for example, to control operation of a cooling fan or take other control actions based on the heatsink temperature. In one implementation, the semiconductor die 116 includes a temperature measurement circuit configured to measure a temperature of the second conductive terminal 118, for example, using a thermistor, thermal couple, etc. (not shown). In this or another example, the semiconductor die 116 can include a voltage measurement circuit that is configured to measure a voltage of the second conductive terminal 118 (e.g., a voltage of an installed heatsink). In these or other examples, the semiconductor die 116 can be configured to provide a measurement signal to the first conductive terminal 113, for example, to provide a measurement signal to a circuit of a host circuit board (not shown). In these or other examples, one of the first conductive terminals 113 can be electrically coupled to a respective one of the second conductive terminals 118, for example, to electrically couple a heatsink to a circuit or component of the host circuit board.

FIG. 1E shows a bottom view of an alternate implementation of the heatsink standoff device 100 having certain features as described above in connection with FIGS. 1-1D. In the example of FIG. 1E, the substrate 110 has semi radial bottom side conductive terminals 113. In one example, the bottom level of the multilevel substrate 110 includes patterned conductive features 113 that form four semi radial conductive metal solder pads configured to be soldered to corresponding solder pads of a host circuit board. In this example, the semi radial pattern corresponds to a circuit board layout that can accommodate conventional metal standoffs. The semi radial conductive terminals 113 in this example allow the heatsink standoff device 100 to be soldered to a circuit board designed for use with conventional metal standoffs.

FIG. 1F shows a partial view of a system with a circuit board 120 having a top side with conductive pads 121 soldered to the conductive terminals 113 along the bottom or first side 111 of the example heatsink standoff device 100 described above in connection with FIGS. 1-1D. The system includes an electronic component 122, such as a semiconductor die or a packaged integrated circuit. The electronic component 122 is laterally spaced apart from the conductive pads 121 along the second direction Y in the illustrated orientation. The electronic component 122 has a bottom or first side attached to the top side of the circuit board 120, for example, by solder connections of one or more terminals (not shown) of the electronic component 122 to corresponding solder pads 123 along the top side of the circuit board 120. A thermal interface material 124 extends on an opposite top or second side of the electronic component 122. The system includes a thermally conductive heatsink 126 attached to the top or second side 102 of the heatsink standoff device 100. In certain examples, the heatsink standoff device 100 can include thermally conductive material (e.g., the materials of the package structure 108 and/or of the substrate 110) to advantageously transfer heat from the attached circuit board 120 to the heatsink 126 to improve system thermal performance.

In one example, the heatsink 126 is electrically conductive (e.g., metal) and the tops of the second conductive terminals 118 of the heatsink standoff device 100 form respective electrical connections to the heatsink 126. In addition, the second conductive terminals 118 provide a thermal connection to the heatsink 126. The heatsink standoff device 100 enables measurement of one or more operating characteristics of the heatsink 126, for example, temperature, voltage, etc., using circuitry of the circuit board 120 and/or circuitry or components of the heatsink standoff device 100 (e.g., semiconductor die 116). The first side 101 of the heatsink standoff device 100 is attached to the top side of the circuit board 120. The conductive terminals 113 along the first side 101 of the heatsink standoff device 100 are soldered to the conductive pads 121 of the circuit board 120. The bottom side of the heatsink 126 has a first portion contacting the thermal interface material 124 above the electronic component 122, as well as a second portion that is attached to the second side 102 of the heatsink standoff device 100.

The opening 107 of the heatsink standoff device 100 extends through the package structure 108 and through the substrate 110 from the first side 101 to the second side 102. The system in one example includes a fastener 128 that extends through the opening 107 to secure the heatsink 126 to the heatsink standoff device 100. The fastener 128 in the illustrated example extends at least partially into an opening of the heatsink 126, although not a requirement of all possible implementations. Any form of fastener can be used, such as a screw, bolt, etc., and the fastener 128 can include threads that engage corresponding threads of the heatsink 126. In another example, a bolt fastener can be used with a corresponding nut (not shown) that engages the top side of the heatsink 126 and/or the bottom side of the circuit board 120. In another implementation, the second portion of the bottom side of the heatsink 126 can be attached to the top side 102 of the heatsink standoff device 100 using a thermally conductive adhesive, which may be electrically conductive, although not a requirement of all possible implementations.

In the illustrated example, the first conductive terminals 113 are electrically coupled to one or more circuits or components of the circuit board 120 and the second conductive terminals 118 are electrically coupled to the heatsink 126. In this implementation, moreover, the semiconductor die 116 is electrically coupled to at least some of the first and second conductive terminals 113 and 118. This configuration allows circuits or components of the semiconductor die 116 to measure heatsink temperature, voltage, etc., while the heatsink standoff device 100 also provides mechanical support for the heatsink 126 and controls the spacing H between the bottom side of the heatsink 126 and the top side of the circuit board 120.

FIGS. 1G and 1H show another example rectangular heatsink standoff device 130 with a bottom side substrate and a circular opening. The heatsink standoff device 130 includes similarly numbered structures and features as described above in connection with FIGS. 1-1D, with no semiconductor die (e.g., the semiconductor die 116 of FIGS. 1-1D is omitted). In one implementation, the substrate 110 in FIGS. 1G and 1H provides direct electrical coupling of respective ones of the top sides of the metal clips 118 to a corresponding one of the first conductive terminals 113. The heatsink standoff device 130 can be constructed using the same substrate 110 as described above in connection with the heatsink standoff device 100 of FIGS. 1-1D, with no semiconductor die. This allows construction of the heatsink standoff device 130 using a common substrate 110 to reduce cost. The electrical interconnection of the substrate 110 in one example allows circuitry or components of a host printed circuit board to perform voltage, temperature, or other measurements of the operating condition of an attached heatsink while concurrently providing mechanical support for the heatsink and controlled spacing of the distance H between the host circuit board and the heatsink.

Referring also to FIGS. 1I-1L, other shapes and forms can be used for the heatsink standoff device. FIGS. 1I-1L illustrate another example heatsink standoff device 140 having similarly numbered structures and features as described above in connection with FIGS. 1-1D, where the package structure 108 has a cylindrical shape with a single annular outer side. In the illustrated example, the substrate 110 also has a cylindrical shape with an annular or radial outer side wall, although not a requirement of all possible implementations. In another example, a rectangular substrate 110 can be used (e.g., as shown above in FIG. 1-1D) with a cylindrical molded package structure 108 that can in certain examples enclose the lateral sidewalls of the substrate 110. Like the above heatsink standoff devices, the device 140 in FIGS. 1I-1L includes a bottom side substrate 110 as well as a circular opening 107 that extends through the package structure 108 and through the substrate 110 between the first and second sides 101 and 102. The illustrated example includes a semiconductor die 116 (e.g., alone or in combination with additional electronic components and/or semiconductor dies, not shown). In another implementation, the semiconductor die 116 can be omitted.

Referring also to FIGS. 1M-1P, in other possible implementations a heatsink standoff device can be constructed without the metal clips 118 and a lateral side substrate 110 can be used to provide bottom and top side electrical terminals 113 and 152, respectively.

FIGS. 1M and 1N show one example heatsink standoff device 150 having similarly numbered structures and features as those described above. The example heatsink standoff device 150 has a rectangular shape, a lateral side substrate 110 and a circular opening 107. The substrate 110 in this example includes an outer first side 111 and an inner second side 112 that is covered by the package structure 108. In the illustrated example, the first side 111 of the substrate 110 has no conductive metal features, and the exposed lateral side 111 is just dielectric material of the multilevel substrate structure, as best shown in FIG. 1N. In this example, the trace and via layers of the substrate 110 include conductive metal features that form the top side second contacts 152 as well as the bottom side first conductive contacts 113. In addition, this example provides conductive trace and via features that allow connection of terminals of the semiconductor die 116 to the top side second contacts 152, for example, to measure a temperature, voltage, or other operating parameter of an installed heatsink (not shown). In addition, one or more of the top side second contacts 152 are electrically coupled with a corresponding bottom side first conductive contact 113, although not a requirement of all possible implementations.

FIGS. 1O and 1P illustrate yet another example heatsink standoff device 160 having similarly numbered structures and features as those described above. The example heatsink standoff device 160 has a rectangular shape, a lateral side substrate 110 and a circular opening 107. The substrate 110 in this example includes an exposed outer first side 111 and an inner second side 112 that is covered by the package structure 108. In the illustrated example, the first side 111 of the substrate 110 has no conductive metal features, and the exposed lateral side 111 is just dielectric material of the multilevel substrate structure, as best shown in FIG. 1O. In this example, the semiconductor die is omitted and the trace and via layers of the substrate 110 include conductive metal features that form the top side second contacts 162 as well as the bottom side first conductive contacts 113. In addition, this example provides conductive trace and via features that electrically couple one or more of the top side second contacts 162 two a corresponding bottom side first conductive contact 113, although not a requirement of all possible implementations.

Referring also to FIGS. 1Q-1S, a variety of different shapes and forms and positions can be used for the various features in different implementations of a heatsink standoff device. FIG. 1Q shows a bottom view of another example heatsink standoff device 170 having a rectangular shape and a rectangular opening 107 with planar sidewalls. This example can include a bottom side substrate with optional top side contacts formed by suitable metal clips, lead frame features, etc. (e.g., FIG. 1 above). The opening 107, in this example, is a rectangular shape (e.g., a square) with four planar opening sidewalls. In other examples, different opening profiles can be used, including one or more curvilinear, planar, or other shaped sidewalls or combinations thereof (not shown).

FIG. 1R shows a bottom view of another example heatsink standoff device 180 having an octagonal shape and a circular opening. The heatsink standoff device 180 in the illustrated example can include a bottom side substrate with optional top side contacts formed by suitable metal clips, lead frame features, etc. (e.g., FIG. 1 above). The opening 107 in this example is a circular shape with a single curvilinear opening sidewall, although other shapes can be used in different implementations (e.g., a square or rectangular opening as shown in FIG. 1Q). In the illustrated example, the lateral sidewalls of the heatsink standoff device 180 are approximately planar, although not a requirement of all possible implementations. In other examples, any number of planar, curvilinear, or other shaped sidewalls can be used.

FIG. 1S shows a bottom view of another example heatsink standoff device 190 with a cylindrical shape, a circular opening 107 and semi radial bottom side terminals 113. In one implementation, the heatsink standoff device 190 has a substrate (e.g., substrate 110 in FIGS. 1-1D above), with the bottom or first side 111 having semi radial bottom side conductive terminals 113, such as conductive metal solder pads configured to be soldered to corresponding solder pads of a host circuit board. In this example, like in the example of FIG. 1E above, the semi radial pattern of the conductive terminals 113 corresponds to a circuit board layout that can accommodate conventional metal standoffs to allow the heatsink standoff device 190 to be soldered to a circuit board designed for use with conventional metal standoffs.

Referring also to FIGS. 1T and 1U, certain implementations can incorporate internal circuitry into the heatsink standoff device. In certain examples, this facilitates measurement of one or more operating parameters or characteristics of an installed heatsink, such as heatsink voltage, heatsink temperature, heatsink humidity, etc.

FIG. 1T shows an example heatsink temperature sense circuit that can be implemented in a heatsink standoff device using discrete components enclosed by the package structure 108, such as soldered to a substrate 110 and/or implemented in the semiconductor die 116 in one implementation of the heatsink standoff device 100 of FIG. 1. In this example, the semiconductor die 116 includes a voltage input terminal soldered to a conductive feature of the substrate 110 to receive a bias voltage input VBIAS from a host circuit board (e.g., via a corresponding first conductive terminal 113 soldered to a conductive feature 121 of the circuit board 120 in FIG. 1F above). The semiconductor die 116 in this example also includes a ground terminal for connection to a circuit ground of the circuit board 120 by a corresponding conductive terminal 113. The semiconductor die 116 includes a bias resistor RBIAS and a temperature sensitive thermistor RTEMP connected in series with one another between the voltage input terminal and the ground terminal. The semiconductor die 116 in this example also includes a signal output terminal connected by the substrate 110 and a corresponding conductive terminal 113 to provide a voltage output signal VTEMP that represents the temperature of an installed heatsink (e.g., 126 in FIG. 1F). In one implementation, one or more of the conductive clips 118 are in thermal contact with the installed heatsink 126 and the semiconductor die 116 is mounted to the substrate 110 in proximity to one or more of the clips 118 such that the thermistor RTEMP can measure the heatsink temperature and the output signal VTEMP provides a voltage signal relative to the voltage of the ground terminal that represents the heatsink temperature.

FIG. 1U shows an example heatsink voltage sense circuit that can be implemented in the semiconductor die 116 or in discrete components within a heatsink standoff device, for example the device 100 described above. In this example, the semiconductor die 116 includes an op amp or other amplifier circuit that receives a heatsink voltage input signal VHS from one or more of the second conductive terminals 118 (e.g., metal clips in contact with an installed heatsink 126). In the illustrated example, the input signal is connected to a non-inverting input of an op amp, and the inverting op amp input is connected to first and second resistors R1 and R2, respectively. The first resistor R1 is connected between the inverting input and a ground or reference terminal. The second resistor R2 is a feedback resistor that is connected between the op amp output and the inverting input to form a non-inverting amplifier that provides an output signal VOUT relative to the ground terminal. The substrate 110 in one example provides electrical interconnections to route the output signal VOUT via one of the first conductive contacts 113 to a circuit or component of the host circuit board 120.

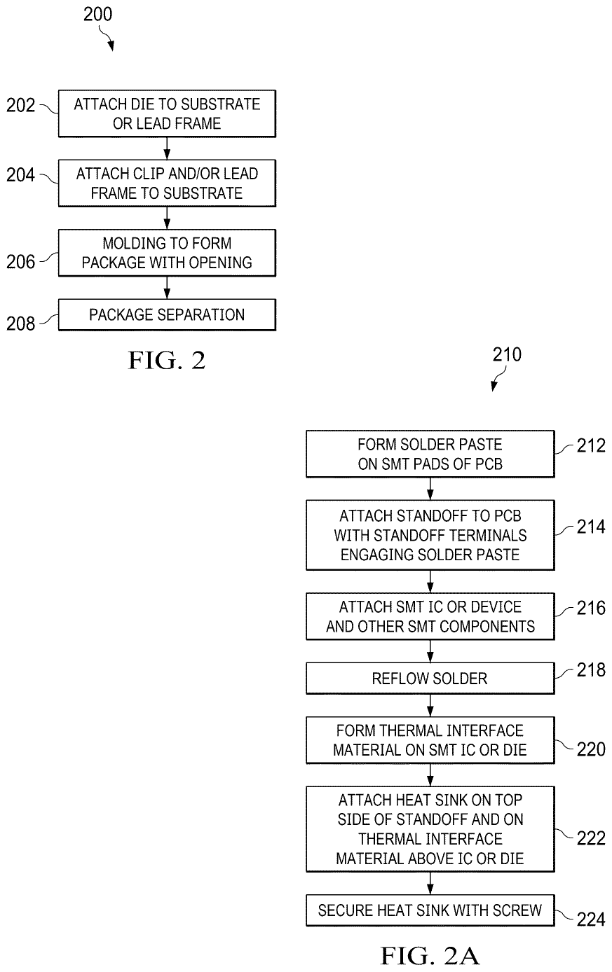

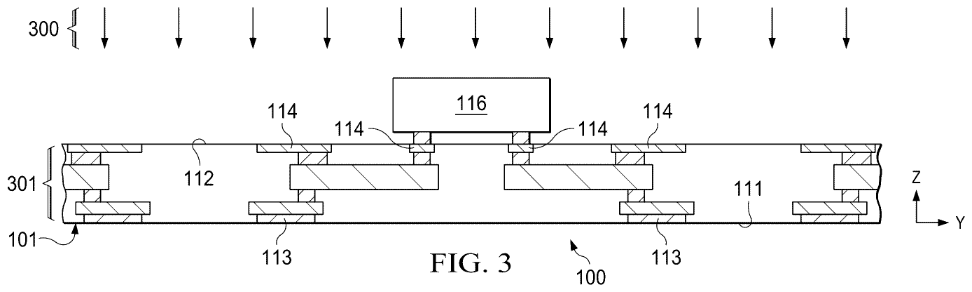

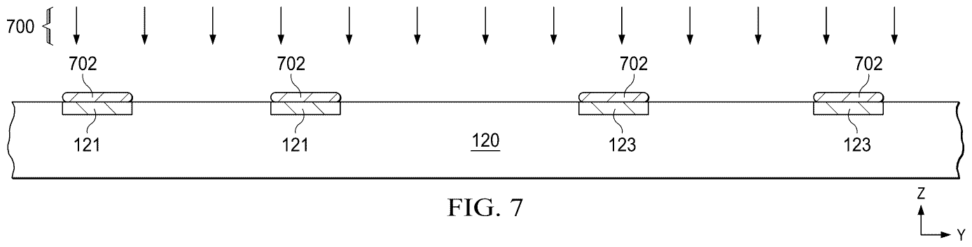

Referring now to FIGS. 2-13, FIG. 2 shows an example method 200 of fabricating a heatsink standoff device, FIG. 2A shows an example system assembly method 210, FIGS. 3-6 illustrate the example heatsink standoff device 100 of FIGS. 1-1D undergoing fabrication processing according to an implementation of the method 200 of FIG. 2, and FIGS. 7-13 illustrate the system of FIG. 1F undergoing processing according to one implementation of the method 210 of FIG. 2A.

The method 200 begins at 202 in FIG. 2 with attaching a semiconductor die (and/or other component or components) to a substrate or lead frame. FIG. 3 shows one example, in which a die attach process 300 is performed that attaches the semiconductor die 116 to a substrate panel array 301. In one implementation, the process 300 attaches the semiconductor die 116 by a flip chip soldering process to corresponding conductive metal features along the second side 112 of one unit area of the substrate panel array 301. The illustrated example uses a starting multilevel package substrate with multiple unit areas arranged in rows and columns, one of which is shown in the figures. In the illustrated example, the flip chip die attach process 300 includes attaching solder dipped conductive metal pillars or solder bumps along the bottom side of the semiconductor die 116 to corresponding conductive metal features 114 on the second side 112 of the substrate panel array 301 in the illustrated unit area, for example, using automated pick and place equipment (not shown). The attachment of the semiconductor die 116 is followed in one example by thermal processing to reflow the solder and form solder connections between the terminals of the semiconductor die 116 and the unit area of the substrate panel array 301. In one implementation, the process 300 can also include forming the underfill material (e.g., dispensing) between the bottom side of the semiconductor die 116 and the top side 112 of the substrate panel array 301, as well as optional underfill material curing (e.g., thermal, UV, etc.). The same process 300 can be used to attach any other included components (not shown) along the second side 112 of the substrate panel array 301.

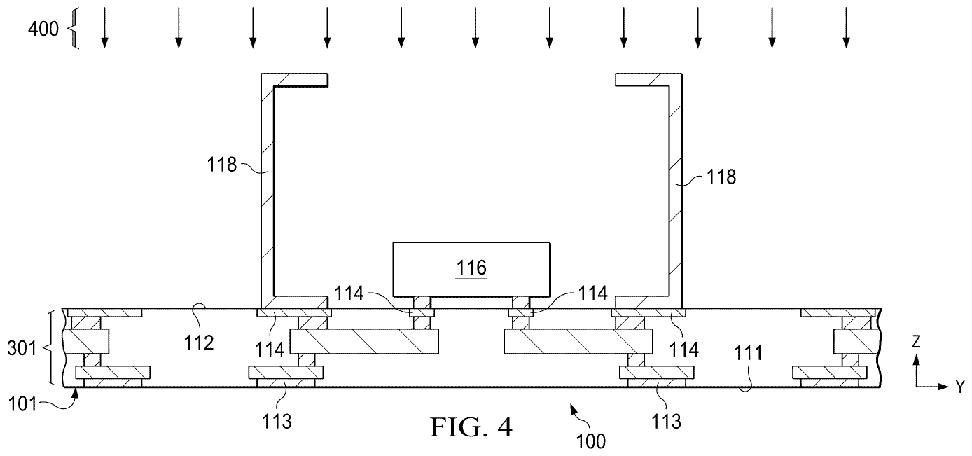

At 204 in FIG. 2, the example method 200 further includes attaching one or more metal clips 118 and/or a lead frame (not shown) to the substrate panel array 301. FIG. 4 illustrates one example, in which a clip attachment process 400 is performed that attaches the metal clips 118 to corresponding conductive features 114 along the second side 112 in each unit area of the substrate panel array 301, for example, using automated pick and place equipment (not shown). In one implementation, the clip attachment process 400 can be a continuation of the die attach process 300 shown in FIG. 3, although not a requirement of all possible implementations. In one example, the clip attachment process includes dispensing, printing, or otherwise forming solder paste along respective conductive features 114 corresponding to the desired locations of the metal clips 118, followed by automated pick and place attachment of the clips 118 and thermal solder reflowing to form solder connections between the bottoms of the clips 118 and the corresponding substrate conductive features 114.

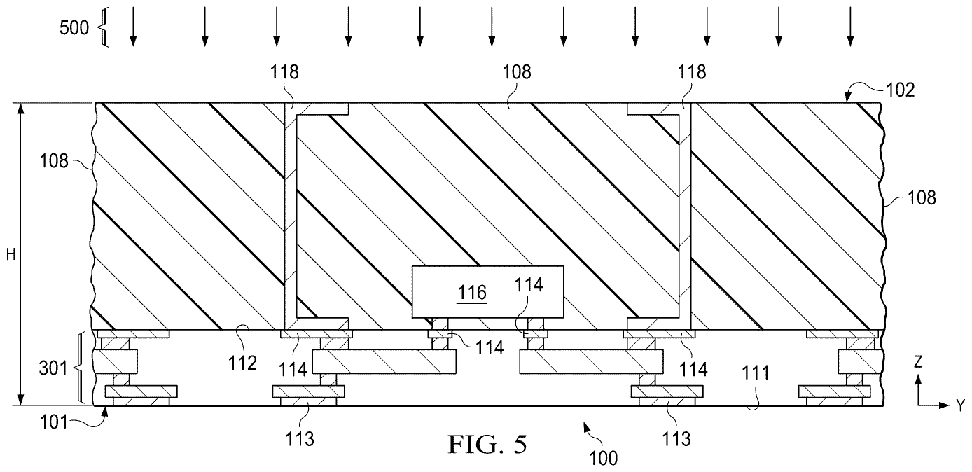

The method 200 of FIG. 2 continues at 206 with molding to form a package structure with an opening. FIG. 5 shows one example, in which a molding process 500 is performed that forms the package structure 108. In one example, the molding process 500 uses a mold (not shown) with a single cavity for each individual unit area of the substrate panel array structure 301. In another implementation, the mold can have a shared cavity that extends across multiple unit areas of the substrate panel 301, for example, along rows or columns of the array structure. In the illustrated example, the molding process 500 creates a single shared molded package structure 108 along multiple unit areas in each column of the substrate panel array structure 301 using a mold to form the package structure 108 including the top or second side 102 that exposes the top side of the metal clips 118.

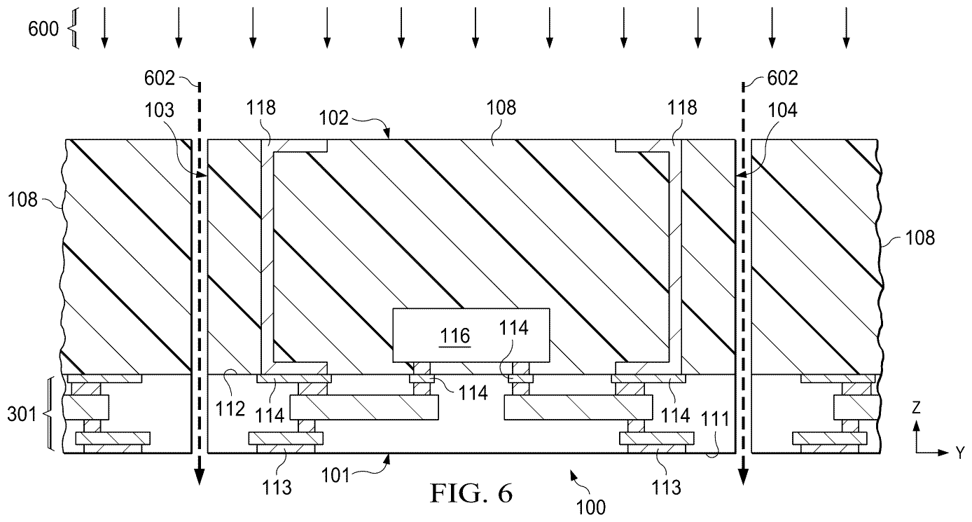

The method 200 continues at 208 in FIG. 2 with package separation in order to separate individual heatsink standoff devices 100 from the starting substrate panel array 301. FIG. 6 shows one example, in which a package separation process 600 is performed that separates adjacent heatsink standoff devices 100 from one another. Any suitable package separation process can be used. In one example, the process 600 includes laser or saw cutting along lines 602 in each column of the substrate panel array 301 to separate the individual heatsink standoff devices 100 from one or more nearest neighbor unit areas in adjacent rows.

Referring now to FIGS. 2A and 7-13, the method 210 begins at 212 in FIG. 2A with forming solder paste on surface mount technology (SMT) pads of a printed circuit board (PCB). FIG. 7 shows one example, in which a solder paste formation process 700 is performed that forms solder paste 702 on corresponding solder pads 121 and 123 of the illustrated portion of the circuit board 120 (e.g., also shown in FIG. 1F above). Any suitable solder paste formation process 700 can be used, for example, dispensing, printing, silk screening, etc.

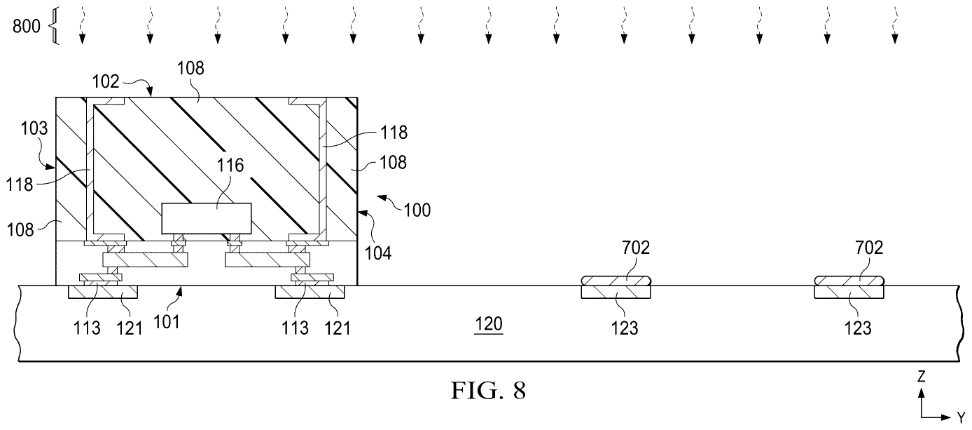

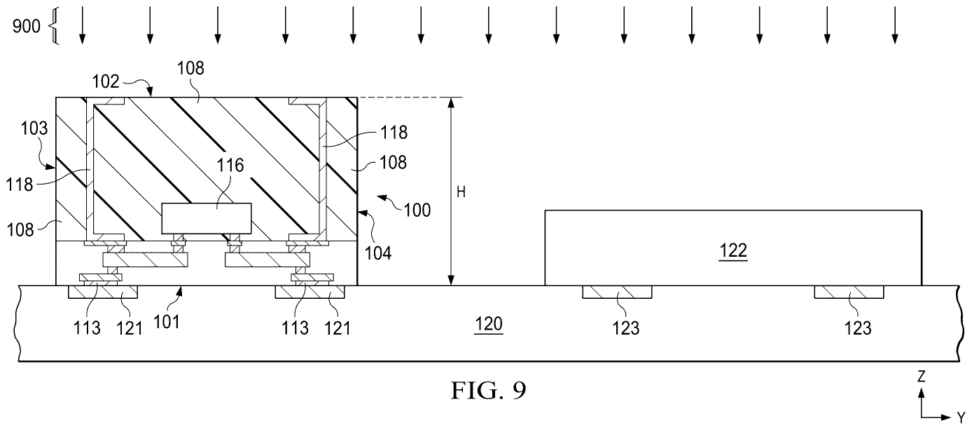

The method 210 continues at 214 in FIG. 2A with attaching the heatsink standoff device 100 to the circuit board 120. FIG. 8 shows one example, in which a component attachment process 800 is performed that attaches the heatsink standoff device 100 to the circuit board 120, for example, using automated pick and place equipment (not shown). The attachment process 800 positions the heatsink standoff device 100 with the first conductive terminals 113 contacting the solder paste (not shown in FIG. 8) that was previously formed on the solder pads 121 of the circuit board 120. 216 in FIG. 2A, the method 200 continues with attaching other components, such as semiconductor dies, passive components, etc. to other locations along the top side of the circuit board 120. FIG. 9 shows one example, in which a component attachment process 900 is performed that attaches the electronic component 122 (e.g., a semiconductor die or other electronic component) to the circuit board 120 with the component terminals contacting the solder paste previously formed on the solder pads 123 of the circuit board 120. In one example, the process 900 is a continuation of the process 800, such as a single surface mount device attachment process that attaches all desired components including the heatsink standoff device 100 and the electronic component 122 to the circuit board 120.

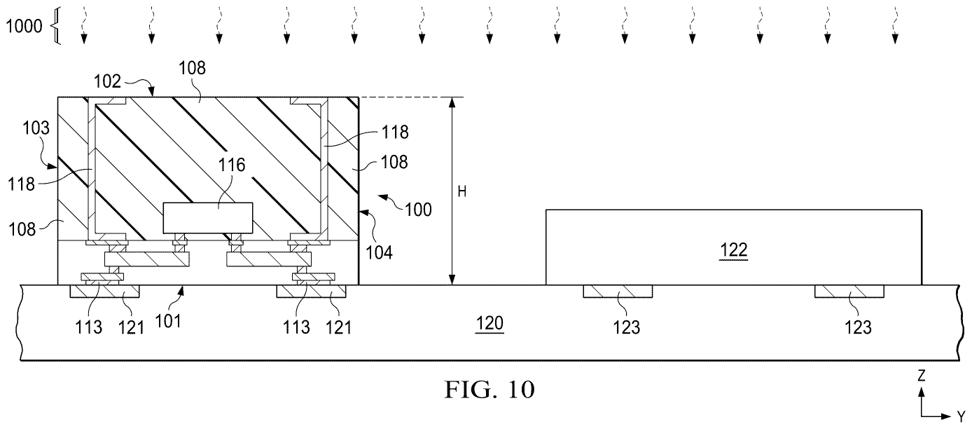

The method 210 continues at 218 in FIG. 2A with thermal processing to reflow the solder paste and form solder connections. FIG. 10 shows one example, in which a thermal reflow process 1000 is performed that reflows the solder paste (e.g., solder paste 702 shown in in FIG. 7 above) to form solder connections between the first conductive terminals 113 of the heatsink standoff device 100 to the corresponding solder pads 121 and to form solder connections between the terminals of the electronic component 122 and the solder pads 123 of the circuit board 120.

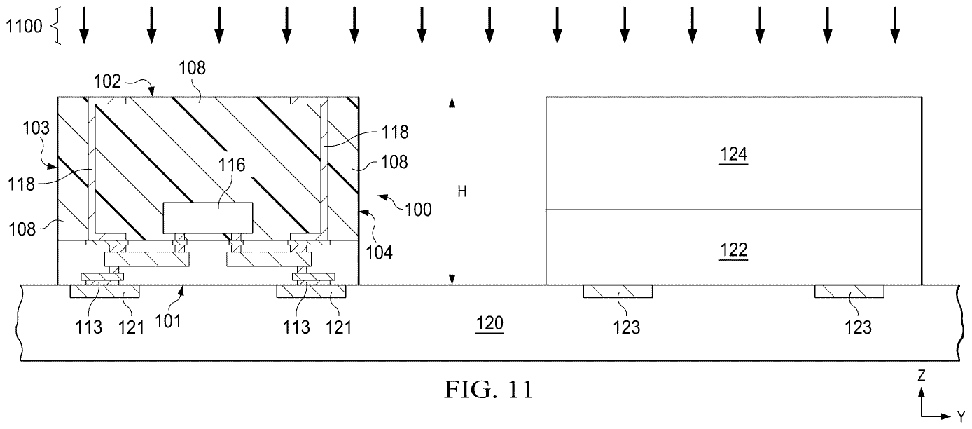

The method 210 continues at 220 in FIG. 2A with thermal interface material formation. FIG. 11 shows one example, in which a process 1100 is performed that forms the thermal interface material 124 along the top side of the electronic component 122. In one example, the thermal interface material 124 can be an adhesive, although not a requirement of all possible implementations. Any suitable process 1100 can be used that preferably forms the thermal interface material 124 such that the total thickness along the third direction Z of the electronic component 122 and the thermal interface material 124 above the top side of the circuit board 120 is approximately equal to or slightly greater than the height H of the heatsink standoff device 100 (e.g., the distance between the top or second side 102 of the heatsink standoff device 100 and the top side of the circuit board 120). The thickness of the formed thermal interface material 124 can be set to allow for a suitable amount of compression of the thermal interface material 124 along the third direction Z during subsequent attachment of a heatsink using a fastener.

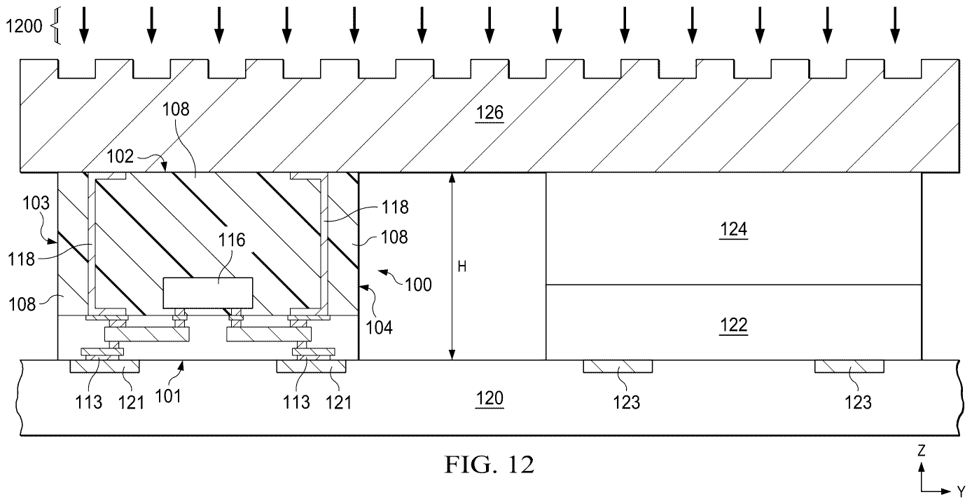

The method 200 continues at 222 in FIG. 2A with attaching the heatsink on the top side of the heatsink standoff device 100 and the top side of the thermal interface material 124 above the electronic component 122. FIG. 12 shows one example, in which an attachment process 1200 is performed (e.g., using pick and place equipment, not shown) that attaches a first portion of the bottom side of the heatsink 126 to the top side of the thermal interface material 124 and attaches a second portion of the heatsink 126 attached to the second side 102 of the heatsink standoff device 100. The attachment process 1200 in one example can include an optional thermal interface material curing step, for example, by thermal processing, UV exposure, etc. In another example, the thermal interface material curing step can be omitted.

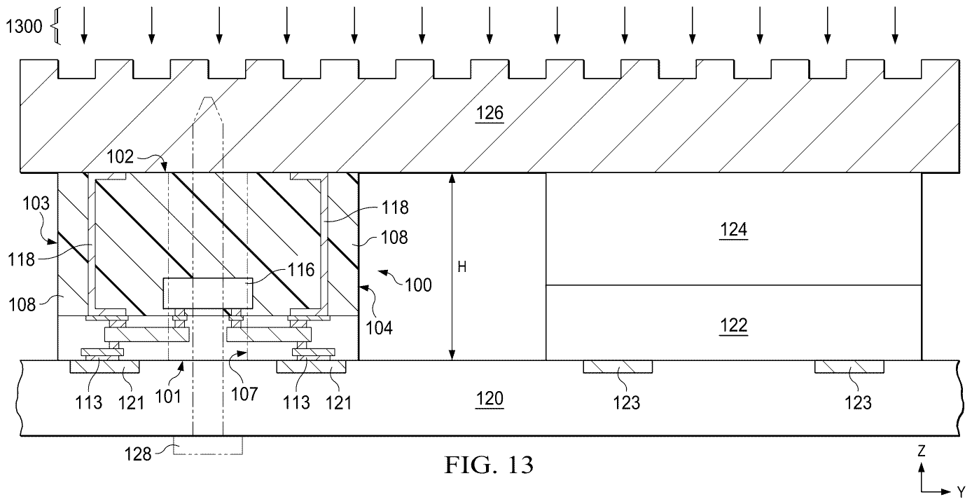

In one example, the method 210 in FIG. 2A includes securing the heatsink with a screw or other fastener at 224. FIG. 13 shows one example, in which a heatsink securing process 1300 is performed that secures the heatsink 126 with a screw fastener 128. In the illustrated example, the fastener 128 is inserted through a hole in the circuit board 120 from the bottom side of the circuit board 120, with the fastener 128 extending through the opening 107 of the heatsink standoff device 100 and being rotated into a threaded opening in the bottom side of the heatsink 126. In another example, the heatsink 126 can have an opening that extends through the heatsink, and a threaded fastener (e.g., a bolt) is inserted from the bottom of the circuit board through a hole in the circuit board 120 and through the opening 107 of the heatsink standoff device 100, and a nut (not shown) is threaded onto the top portion of the bolt fastener. In another example, the fastener and the securing step at 224 in FIG. 2A can be omitted, where the heatsink 126 is secured to the top side of the heatsink standoff device 100 and to the thermal interface material 124 by an adhesive (not shown).

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

What is claimed is:

1. A heatsink standoff device, comprising:
opposite first and second sides;
a package structure;
an opening that extends through the package structure from the first side to the second side; and
a conductive terminal exposed outside the first side and configured to be soldered to a circuit board.

2. The heatsink standoff device of claim 1, wherein the heatsink standoff device has substantially planar lateral sides.

3. The heatsink standoff device of claim 1, wherein the heatsink standoff device has a cylindrical shape.

4. The heatsink standoff device of claim 1, further comprising a semiconductor die electrically coupled to the conductive terminal.

5. The heatsink standoff device of claim 4, wherein:
the conductive terminal is a first conductive terminal exposed outside the first side;
the heatsink standoff device further comprises a second conductive terminal exposed outside the second side and configured to be electrically coupled to a heatsink; and
the semiconductor die is electrically coupled to the second conductive terminal.

6. The heatsink standoff device of claim 5, wherein the semiconductor die includes a temperature measurement circuit configured to measure a temperature of the second conductive terminal.

7. The heatsink standoff device of claim 5, wherein the semiconductor die includes a voltage measurement circuit configured to measure a voltage of the second conductive terminal.

8. The heatsink standoff device of claim 5, wherein the semiconductor die is configured to provide a measurement signal to the first conductive terminal.

9. The heatsink standoff device of claim 1, wherein:
the conductive terminal is a first conductive terminal exposed outside the first side;
the heatsink standoff device further comprises a second conductive terminal exposed outside the second side and configured to be electrically coupled to a heatsink; and
the first conductive terminal is electrically coupled to the second conductive terminal.

10. The heatsink standoff device of claim 9, further comprising a substrate having conductive trace and via features that include the first conductive terminal.

11. The heatsink standoff device of claim 10, wherein the conductive trace and via features of the substrate include the second conductive terminal.

12. The heatsink standoff device of claim 1, further comprising a substrate having conductive trace and via features that include the first conductive terminal.

13. The heatsink standoff device of claim 12, further comprising a clip extending from the substrate to the second side and forming a second conductive terminal exposed outside the second side and configured to be electrically coupled to a heatsink.

14. The heatsink standoff device of claim 1, wherein the opening has a circular shape.

15. The heatsink standoff device of claim 1, wherein the opening has a planar inner side wall.

16. A system, comprising:
a circuit board having a side with a conductive pad;
an electronic component spaced apart from the conductive pad and having a first side attached to the side of the circuit board;
a thermal interface material on an opposite second side of the electronic component;
a heatsink standoff device, comprising:
a first side attached to the side of the circuit board;
an opposite second side;
a package structure;
an opening that extends through the package structure from the first side to the second side; and
a conductive terminal exposed outside the first side and soldered to the conductive pad of the circuit board; and
a heatsink having a side with a first portion contacting the thermal interface material and a second portion attached to the second side of the heatsink standoff device.

17. The system of claim 16, further comprising a fastener extending through the opening to secure the heatsink to the heatsink standoff device.

18. The system of claim 17, wherein the fastener extends at least partially into an opening of the heatsink.

19. The system of claim 16, wherein:
the conductive terminal is a first conductive terminal exposed outside the first side; and
the heatsink standoff device further comprises:
a second conductive terminal exposed outside the second side and electrically coupled to the heatsink; and
a semiconductor die electrically coupled to the first and second conductive terminals.

20. A method of making a heatsink standoff device, the method comprising:
forming a package structure having a first side and an opposite second side;
forming a conductive terminal exposed outside the first side of the package structure; and
forming an opening that extends through the package structure from the first side to the second side.
